(19) United States
(12) Patent Application Publication
(10) Pub. No.: US 2025/0096081 A1
(43) Pub. Date: Mar. 20, 2025

(54) SEMICONDUCTOR PACKAGE HAVING INTERPOSER AND METHOD OF MAKING THE SAME

(71) Applicant: ALPHA AND OMEGA SEMICONDUCTOR INTERNATIONAL LP, Toronto (CA)

(72) Inventors: Madhur Bobde, Sunnyvlae, CA (US); Yan Xun Xue, Los Gatos, CA (US); Long-Ching Wang, Cupertino, CA (US); Jian Yin, San Ramon, CA (US); Sitthipong Angkititrakul, Dublin, CA (US)

(73) Assignee: ALPHA AND OMEGA SEMICONDUCTOR INTERNATIONAL LP, TORONTO, ON (CA)

(21) Appl. No.: 18/368,557

(22) Filed: Sep. 14, 2023

(51) Int. Cl. H01L 23/495; H01L 21/56; H01L 23/00; H01L 23/31; H01L 23/552

(52) U.S. Cl. CPC H01L 23/49562; H01L 21/565; H01L 23/3107; H01L 23/49503; H01L 23/552; H01L 24/48; H01L 2224/48247; H01L 2924/13091; H01L 2924/3025

(57) ABSTRACT

A semiconductor package comprising a lead frame, a low side field-effect transistor (FET), a high side FET, a metal clip, an interposer, an integrated circuit (IC) controller, and a molding encapsulation. A method, for fabricating a semiconductor package, comprises the steps of: providing a lead frame; attaching a low side FET and a high side FET; mounting a metal clip; attaching an interposer; mounting an IC controller, forming a molding encapsulation; and applying a singulation process.

### FIELD OF THE INVENTION

This invention relates generally to a semiconductor package operative to provide electromagnetic interference (EMI) shielding and capacitance shielding. More particularly, the present invention relates to a power semiconductor package having an interposer and a method of making the power semiconductor package.

### BACKGROUND OF THE INVENTION

A conventional power semiconductor package disposes a high-side field-effect transistor (FET), a low-side FET, and an integrated circuit (IC) controller side-by-side so as to result in a larger package size.

The present disclosure stacks the IC controller on an interposer that is mounted on a metal clip connecting the high side FET and the low side FET so as to reduce the package size and to provide EMI shielding and capacitance shielding.

### SUMMARY OF THE INVENTION

The present invention discloses a semiconductor package comprising a lead frame, a low side FET, a high side FET, a metal clip, an interposer, an IC controller, and a molding encapsulation.

The present invention discloses a method for fabricating a semiconductor package. The method comprises the steps of: providing a lead frame; attaching a low side FET and a high side FET; mounting a metal clip; attaching an interposer; mounting an IC controller; forming a molding encapsulation; and applying a singulation process.

### BRIEF DESCRIPTION OF THE DRAWINGS

FIG. 1A shows a perspective view and FIG. 1B shows a side view of a semiconductor package in examples of the present disclosure.

FIG. 2A shows a perspective view and FIG. 2B shows a side view of another semiconductor package in examples of the present disclosure.

FIG. 3 is a flowchart of a process to develop a semiconductor package in examples of the present disclosure.

FIGS. 4A, 4B, 4C, 4D, 4E, 4F, 4G, 4H, 4I, 4J, 4K, and 4L show the steps of the process to fabricate the semiconductor package in examples of the present disclosure.

### DETAILED DESCRIPTION OF THE INVENTION

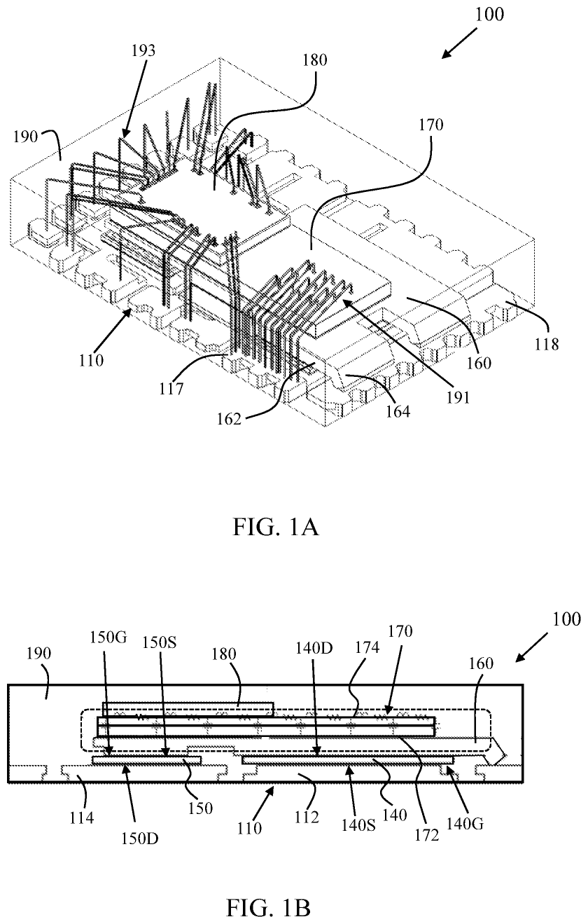

FIG. 1A shows a perspective view and FIG. 1B shows a side view of a semiconductor package 100 in examples of the present disclosure. In one example, the semiconductor package 100 is a power semiconductor package. The semiconductor package 100 comprises a lead frame 110, a low side field-effect transistor (FET) 140, a high side FET 150, a metal clip 160, an interposer 170, an integrated circuit (IC) controller 180, and a molding encapsulation 190. In FIGS. 1A and 1B, the molding encapsulation is shown in transparent for clarity.

The lead frame 110 comprises a first die paddle 112 and a second die paddle 114. The low side FET 140 is flipped and is attached to the first die paddle 112. The low side FET 140 comprises a source electrode 140S and a gate electrode 140G on a top surface of the low side FET 140 and a drain electrode 140D on a bottom surface of the low side FET 140.

The high side FET 150 is attached to the second die paddle 114. The high side FET 150 comprises a source electrode 150S and a gate electrode 150G on a top surface of the high side FET 150 and a drain electrode 150D on a bottom surface of the high side FET 150. The metal clip 160 connects the drain electrode 140D of the low side FET 140 to the source electrode 150S of the high side FET 150. The metal clip 160 comprises a horizontal portion 162 and a slanted portion 164. The horizontal portion 162 has a top surface that is substantially flat. An end of the slanted portion 164 of the metal clip 160 is attached to an end paddle 118 of the lead frame 110 that serves as a switching node output in converter application.

The interposer 170 is attached to a top surface of the metal clip 160. The IC controller 180 is attached to a top surface of the interposer 170. The molding encapsulation 190 encloses the low side FET 140, the high side FET 150, the metal clip 160, the interposer 170, and the IC controller 180. In one example, the molding encapsulation 190 further encloses an entirety of the lead frame 110. In another example, the molding encapsulation 190 further encloses a majority portion (larger than 50%) of the lead frame 110 and a bottom surface of the lead frame 110 is exposed from the molding encapsulation 190.

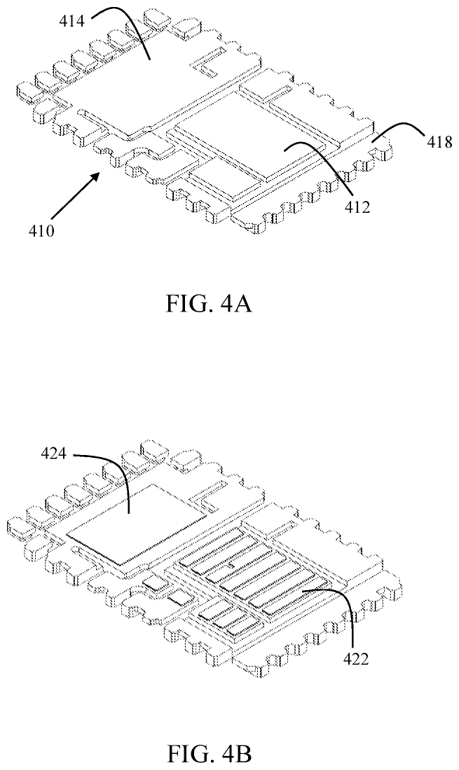

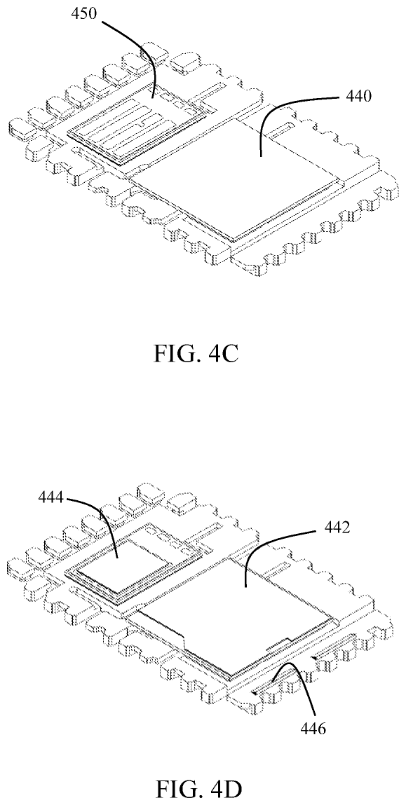

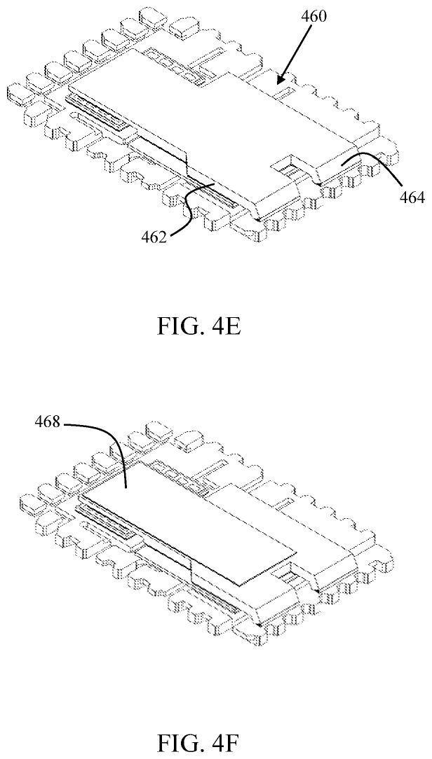

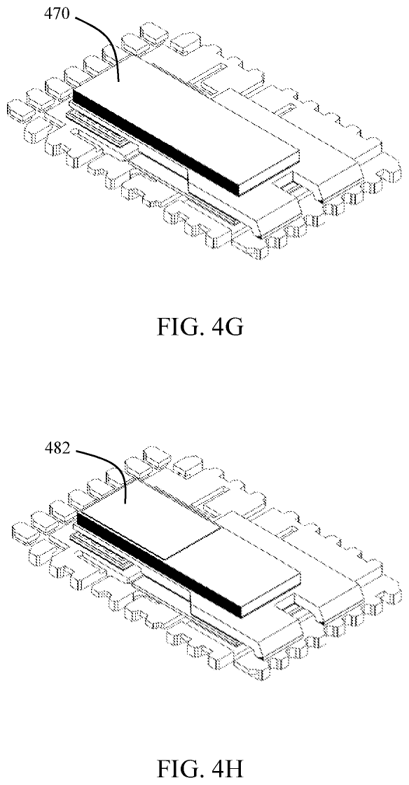

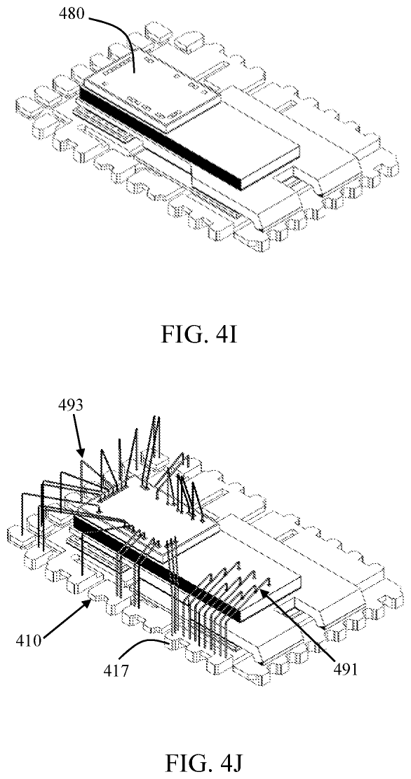

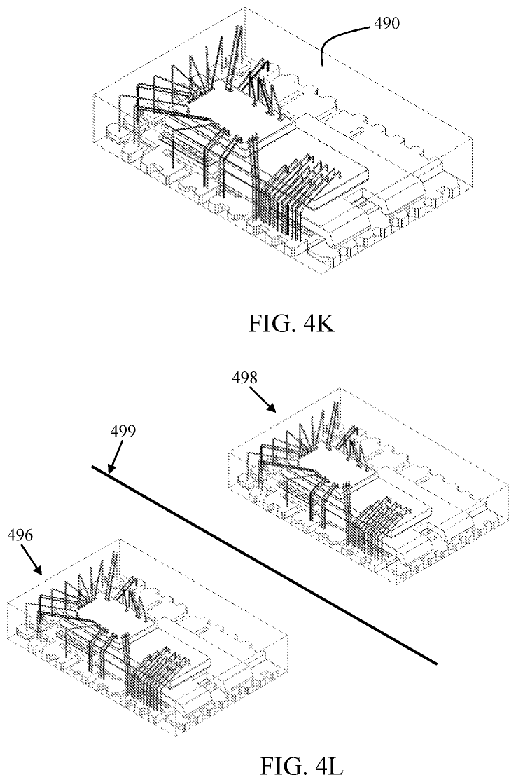

The source electrode 140S of the low side FET 140 is electrically and mechanically connected to the first die paddle 112 by a first conductive material 422 of FIG. 4B. The drain electrode 150D of the high side FET 150 is electrically and mechanically connected to the second die paddle 114 by a second conductive material 424 of FIG. 4B. In examples of the present disclosure, each of the first conductive material 422 and the second conductive material 424 comprises a solder paste material.

The metal clip 160 is electrically and mechanically connected to the drain electrode 140D of the low side FET 140 by a third conductive material 442 of FIG. 4D. The metal clip 160 is electrically and mechanically connected to the source electrode 150S of the high side FET 150 by a fourth conductive material 444 of FIG. 4D. The metal clip 160 is electrically and mechanically connected to the end paddle 118 of the lead frame 110 by a fifth conductive material 446 of FIG. 4D. In examples of the present disclosure, each of the third conductive material 442, the fourth conductive material 444, and the fifth conductive material 446 comprises a solder paste material.

The interposer 170 is attached to a top surface of the metal clip 160 by a first adhesive material 468 of FIG. 4F. In examples of the present disclosure, the first adhesive material 468 comprises a non-conductive epoxy.

The IC controller 180 is attached to a top surface of the interposer 170 by a second adhesive material 482 of FIG. 4H. In examples of the present disclosure, the second adhesive material 482 comprises a non-conductive epoxy.

In examples of the present disclosure, the interposer 170 comprises a lower insulation layer 172 and an upper metal layer 174. In examples of the present disclosure, the interposer 170 is of a first rectangular prism shape; the lower insulation layer 172 is of a second rectangular prism shape; and the upper metal layer 174 is of a third rectangular prism shape. In one example, the lower insulation layer 172 comprises polyimide. In one example, the upper metal layer 174 comprises copper. In another example, the upper metal layer 174 comprises aluminum. In examples of the present disclosure, a thickness of the lower insulation layer 172 is in a range from 0.15 mm to 0.25 mm and a thickness of the upper metal layer 174 is in a range from 5 microns to 15 microns.

In examples of the present disclosure, the semiconductor package 100 further comprises a plurality of bond wires 191 electrically connecting the upper metal layer 174 of the interposer 170 to the first die paddle 112 serving as a power ground terminal 117 of the lead frame 110. Another plurality of bond wires 193 electrically connecting the IC controller 180 to the lead frame 110. Other metal connections such as clips or ribbons may be used to connect the upper metal layer 174 to the power ground terminal 117. The upper metal layer 174 provides EMI and capacitive shielding to the IC controller 180 stacked on it thus prevent electrical interference due to capacitive coupling in the case when the IC controller 180 directly attached to the clip that is connected to high frequency switching node. In examples of the present disclosure, the low side FET 140 and the high side FET 150 are disposed side-by-side. In one example, the low side FET 140 is a metal-oxide-semiconductor field-effect transistor (MOSFET). The high side FET 150 is another MOSFET.

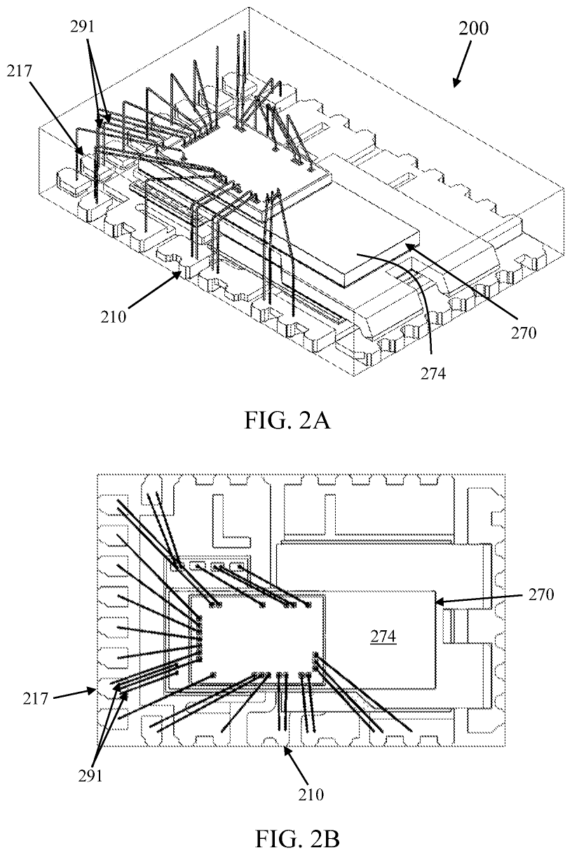

FIG. 2A shows a perspective view and FIG. 2B shows a side view of a semiconductor package 200 in examples of the present disclosure. The semiconductor package 200 of FIG. 2A and FIG. 2B is similar to the semiconductor package 100 of FIG. 1A except that the semiconductor package 200 of FIG. 2A and FIG. 2B comprises a plurality of bond wires 291 electrically connecting the upper metal layer 274 of the interposer 270 to an analog ground terminal 217 of the lead frame 210. The upper metal layer 274 provides EMI and capacitive shielding to the IC controller stacked on it thus prevent electrical interference due to capacitive coupling in the case when the IC controller directly attached to the clip that is connected to high frequency switching node.

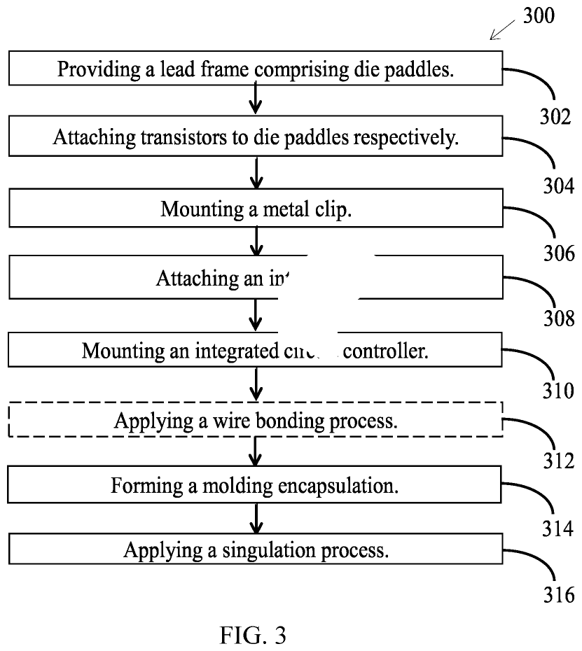

FIG. 3 is a flowchart of a process 300 to develop a power semiconductor package in examples of the present disclosure. The process 300 may start from block 302. For simplicity, only one of the two semiconductor packages of FIG. 4L is shown in FIGS. 4A, 4B, 4C, 4D, 4E, 4F. 4G, 4H, 4I, 4J, and 4K.

In block 302, referring now to FIG. 4A, a lead frame 410 is provided. The lead frame 410 comprises a first die paddle 412 in a middle section, a second die paddle 414 located on a first side of the first die paddle 412, and an end paddle 418 on a second side opposite the first side of the first die paddle 412. The first die paddle has a first die pad cut-off corner adjacent to the second die paddle 414 to accommodate one or more low side gate leads extend into the first die pad cut-off corner. The second die pad has a second die pad cut-off corner diagonally opposite the first die pad cut-off corner to accommodate a lead extending into the second die pad cut-off corner. Block 302 may be followed by block 304.

In block 304, referring now to FIGS. 4B and 4C, transistors are attached to die paddles respectively. Apply a first conductive material 422 on a top surface of the first die paddle 412 of the lead frame 410. Apply a second conductive material 424 on a top surface of the second die paddle 414 of the lead frame 410. A low side FET 440 is flipped and is attached to the first die paddle 412 through the first conductive material 422. The low side FET 440 comprises a source electrode 140S of FIG. 1B and a gate electrode 140G of FIG. 1B on a top surface of the low side FET 440. The high side FET 450 is attached to the second die paddle 414 through the second conductive material 424. The high side FET 450 comprises a source electrode 150S of FIG. 1B and a gate electrode 150G of FIG. 1B on a top surface of the high side FET 450. In examples of the present disclosure, each of the first conductive material 422 and the second conductive material 424 comprises a solder paste material. In examples of the present disclosure, the low side FET 440 and the high side FET 450 are disposed side-by-side. In one example, the low side FET 440 is a MOSFET. The high side FET 450 is another MOSFET. Block 304 may be followed by block 306.

In block 306, referring now to FIGS. 4D and 4E, a metal clip 460 is mounted. Apply a third conductive material 442 on a top surface of the low side FET 440. Apply a fourth conductive material 444 on a top surface of the high side FET 450. Apply a fifth conductive material 446 on a top surface of the end paddle 418. In examples of the present disclosure, each of the third conductive material 442, the fourth conductive material 444, and the fifth conductive material 446 comprises a solder paste material. In examples of the present disclosure, the solder paste material contains lead (Pb). A reflow temperature for the solder paste material is higher than two hundred degrees Centigrade. Mounting a metal clip 460 connecting a drain electrode 140D of FIG. 1B of the low side FET 440 and the source electrode 150S of FIG. 1B of the high side FET 450 to the first end paddle 418 of the lead frame 410. The metal clip 460 comprises a horizontal portion 462 and a slanted portion 464. An end of the slanted portion 464 of the metal clip 460 is attached to an end paddle 418 of the lead frame 410 through the fifth conductive material 446. Block 306 may be followed by block 308.

In block 308, referring now to FIGS. 4F and 4G, an interposer 470 is mounted. Apply a first adhesive material 468 on the metal clip 460. In examples of the present disclosure, the first adhesive material 468 comprises a non-conductive epoxy. Mount the interposer 470 on the first adhesive material 468. In examples of the present disclosure, the interposer 470 comprises an upper metal layer 174 overlaying a lower insulation layer 172 as shown in FIG. 1B. The interposer 470 covers at least 50% of the top surface of the horizontal portion 462 of the metal clip 460, extending from above the high side FET 450 to above the low side FET 440. In a preferred example, the interposer 470 covers at least 75% of the top surface of the horizontal portion 462 of the metal clip 460. In examples of the present disclosure, the interposer 470 is of a first rectangular prism shape; the lower insulation layer 172 is of a second rectangular prism shape; and the upper metal layer 174 is of a third rectangular prism shape. In one example, the lower insulation layer 172 comprises polyimide. In one example, the upper metal layer 174 comprises copper. In another example, the upper metal layer 174 comprises aluminum. In examples of the present disclosure, a thickness of the lower insulation layer 172 is in a range from 0.15 mm to 0.25 mm and a thickness of the upper metal layer 174 is in a range from 5 microns to 15 microns. Alternatively, the interposer 470 may further comprise a bottom metal layer (not shown) and a conductive first adhesive material 468 is used to attached the interposer 470 onto the metal clip 460. Block 308 may be followed by block 310.

In block 310, referring now to FIGS. 4H and 4I, an IC controller 480 is mounted on the interposer 470. Apply a second adhesive material 482 on the interposer 470. In examples of the present disclosure, the second adhesive material 482 comprises a non-conductive epoxy. Mount the IC controller on a top surface of the interposer 470 through the second adhesive material 482. Block 310 may be followed by block 312 or block 314.

In optional block 312 (shown in dashed lines), referring now to FIG. 4J, a wire bonding process is applied. Apply a plurality of bond wires 491 electrically connecting the upper metal layer 174 of FIG. 1B of the interposer 470 to the first die paddle 412 serving as a power ground terminal 417 of the lead frame 410. Apply another plurality of bond wires 493 electrically connecting the IC controller 480 to the lead frame 110.

In another example, a plurality of bond wires 291 of FIG. 2A and FIG. 2B electrically connecting the upper metal layer 274 of FIG. 2A and FIG. 2B of the interposer 470 to an analog ground terminal 217 of FIG. 2A and FIG. 2B of the lead frame 410. Block 312 may be followed by block 314.

In block 314, referring now to FIG. 4K, a molding encapsulation 490 is formed. The molding encapsulation 490 encloses the low side FET 440, the high side FET 450, the metal clip 460, the interposer 470, and the IC controller 480. In one example, the molding encapsulation 490 further encloses an entirety of the lead frame 410. In another example, the molding encapsulation 490 further encloses a majority portion (larger than 50%) of the lead frame 410 and a bottom surface of the lead frame 410 is exposed from the molding encapsulation 490. Block 314 may be followed by block 316.

In block 316, referring now to FIG. 4L, a singulation process along the line 499 is applied. The semiconductor package 496 is separated from an adjacent semiconductor package 498. Although only two power semiconductor packages are shown in FIG. 4L, the number of semiconductor packages to be separated in a same singulation process may vary. In examples of the present disclosure, semiconductor package 496 and the semiconductor package 498 are power semiconductor packages.

Those of ordinary skill in the art may recognize that modifications of the embodiments disclosed herein are possible. For example, a number of bond wires may vary. Other modifications may occur to those of ordinary skill in this art, and all such modifications are deemed to fall within the purview of the present invention, as defined by the claims.

1. A semiconductor package comprising:
a lead frame comprising
a first die paddle; and
a second die paddle;
a low side field-effect transistor (FET) being flipped and attached to the first die paddle, the low side FET comprising
a source electrode and a gate electrode on a top surface of the low side FET; and
a drain electrode on a bottom surface of the low side FET;
a high side FET attached to the second die paddle, the high side FET comprising
a source electrode and a gate electrode on a top surface of the high side FET; and
a drain electrode on a bottom surface of the high side FET;
a metal clip connecting the drain electrode of the low side FET to the source electrode of the high side FET;
an interposer attached to a top surface of the metal clip;
an integrated circuit (IC) controller attached to a top surface of the interposer; and
a molding encapsulation enclosing the low side FET, the high side FET, the metal clip, the interposer, and the IC controller.

2. The semiconductor package of claim 1, wherein the interposer comprises
a lower insulation layer; and
an upper metal layer.

3. The semiconductor package of claim 2 further comprising
a plurality of bond wires electrically connecting the upper metal layer of the interposer to a power ground terminal.

4. The semiconductor package of claim 2 further comprising
a plurality of bond wires electrically connecting the upper metal layer of the interposer to an analog ground terminal.

5. The semiconductor package of claim 1, wherein the low side FET and the high side FET are disposed side-by-side.

6. The semiconductor package of claim 1 further comprising
a plurality of bond wires electrically connecting the IC controller to the lead frame.

7. The semiconductor package of claim 1, wherein the low side FET is a metal-oxide-semiconductor field-effect transistor (MOSFET); and
wherein the high side FET is another MOSFET.

8. The semiconductor package of claim 1, wherein the interposer covers at least 50% of the top surface of the metal clip.

9. The semiconductor package of claim 1, wherein the interposer covers at least 75% of the top surface of the metal clip.

10. A method for fabricating a semiconductor package, the method comprising the steps of:
providing a lead frame comprising
a first die paddle; and
a second die paddle;
attaching a low side field-effect transistor (FET) and a high side FET to the first die paddle, and the second die paddle respectively;
mounting a metal clip connecting a drain electrode of the low side FET to a source electrode of the high side FET;
attaching an interposer to a top surface of the metal clip;
mounting an integrated circuit (IC) controller on a top surface of the interposer;
forming a molding encapsulation enclosing the low side FET, the high side FET, the metal clip, the interposer, and the IC controller; and
applying a singulation process so as to separate the semiconductor package from other semiconductor packages;
wherein the low side FET is flipped.

11. The method of claim 10, wherein the interposer comprises
a lower insulation layer; and
an upper metal layer.

12. The method of claim 11 further comprising the step of
applying a plurality of bond wires electrically connecting the upper metal layer of the interposer to a power ground terminal.

13. The method of claim 11 further comprising the step of
applying a plurality of bond wires electrically connecting the upper metal layer of the interposer to an analog ground terminal.

14. The method of claim 10, wherein the low side FET and the high side FET are disposed side-by-side.

15. The method of claim 10 further comprising
applying a plurality of bond wires electrically connecting the IC controller to the lead frame

16. The method of claim 10, wherein the low side FET is a metal-oxide-semiconductor field-effect transistor (MOSFET); and
wherein the high side FET is another MOSFET.
